(19) United States
(12) Patent Application Publication
(10) Pub. No.: US 2011/0146741 A1
(43) Pub. Date: Jun. 23, 2011

(54) THERMOELECTRIC CONVERSION MODULE AND METHOD FOR MAKING THE SAME

(75) Inventors: Masaharu Hida, Kawasaki (JP); Kazunori Yamanaka, Kawasaki (JP)

(73) Assignee: FUJITSU LIMITED, Kawasaki-shi (JP)

(21) Appl. No.: 12/970,937

(22) Filed: Dec. 17, 2010

(30) Foreign Application Priority Data
Dec. 21, 2009 (JP) 2009-289557

(51) Int. Cl. H01L 35/30; H01L 21/02

(52) U.S. Cl. 136/205; 136/201; 438/55; 257/E21.002

(57) ABSTRACT

A thermoelectric conversion module includes: p-type semiconductor blocks, each including a p-type thermoelectric conversion material, a first column portion and a first coupling portion that projects in a horizontal direction from an end of the first column portion; and n-type semiconductor blocks, each including an n-type thermoelectric conversion material, a second column portion and a second coupling portion that projects in a horizontal direction from an end of the second column portion, wherein the first coupling portions of the p-type semiconductor blocks are respectively coupled to the other ends of the second column portions of the n-type semiconductor blocks, and the second coupling portions of the n-type semiconductor blocks are respectively coupled to the other ends of the first column portions of the p-type semiconductor blocks, and the p-type semiconductor blocks and the n-type semiconductor blocks are alternately arranged and coupled to each other in series.

### CROSS-REFERENCE TO RELATED APPLICATIONS

This application claims the benefit of priority from Japanese Patent Application No. 2009-289557 filed on Dec. 21, 2009, the entire contents of which are incorporated herein by reference.

### BACKGROUND

1. Field

Embodiments discussed herein relate to thermoelectric conversion modules and methods for making the thermoelectric conversion modules.

2. Description of Related Art

Thermoelectric conversion elements may convert wasted thermal energy into electric energy. Because the output voltage of one thermoelectric conversion element is low, a thermoelectric conversion module including a plurality of thermoelectric conversion elements coupled in series may be used.

Related technologies are disclosed in Japanese Laid-open Patent Publication No. H8-43555, Japanese Laid-open Patent Publication No. 2004-288819, Japanese Laid-open Patent Publication No. 2005-5526, and Japanese Laid-open Patent Publication No. 2005-19767, for example.

### SUMMARY

One aspect of the embodiments, a thermoelectric conversion module includes: p-type semiconductor blocks, each including a p-type thermoelectric conversion material, a first column portion and a first coupling portion that projects in a horizontal direction from an end of the first column portion; and n-type semiconductor blocks, each including an n-type thermoelectric conversion material, a second column portion and a second coupling portion that projects in a horizontal direction from an end of the second column portion, wherein the first coupling portions of the p-type semiconductor blocks are respectively coupled to the other ends of the second column portions of the n-type semiconductor blocks, and the second coupling portions of the n-type semiconductor blocks are respectively coupled to the other ends of the first column portions of the p-type semiconductor blocks, and the p-type semiconductor blocks and the n-type semiconductor blocks are alternately arranged and coupled to each other in series.

The object and advantages of the invention will be realized and achieved by at least the features, elements, and combinations particularly pointed out in the claims.

It is to be understood that both the foregoing general description and the following detailed description are exemplary and explanatory and are not restrictive of the invention, as claimed.

### BRIEF DESCRIPTION OF THE DRAWINGS

FIG. 1 illustrates an exemplary thermoelectric conversion module.

FIG. 2 illustrates an exemplary method for making a thermoelectric conversion module.

FIG. 3 illustrates an exemplary method for making a thermoelectric conversion module.

FIGS. 4A and 4B illustrate an exemplary method for making a thermoelectric conversion module.

FIGS. 5A and 5B illustrate an exemplary method for making a thermoelectric conversion module.

FIG. 6 illustrates an exemplary method for making a thermoelectric conversion module.

FIG. 7 illustrates an exemplary method for making a thermoelectric conversion module.

FIG. 8 illustrates an exemplary method for making a thermoelectric conversion module.

FIG. 9 illustrates an exemplary thermoelectric conversion module.

FIG. 10 illustrates an exemplary method for making a thermoelectric conversion module.

FIG. 11 illustrates an exemplary method for making a thermoelectric conversion module.

FIGS. 12A and 12B illustrate an exemplary method for making a thermoelectric conversion module.

FIG. 13 illustrates an exemplary method for making a thermoelectric conversion module.

FIG. 14 illustrates an exemplary method for making a thermoelectric conversion module.

FIG. 15 illustrates an exemplary thermoelectric conversion module.

### DESCRIPTION OF EMBODIMENTS

A thermoelectric conversion module includes two heat transfer plates that sandwich a plurality of semiconductor blocks including a p-type thermoelectric conversion material (referred to as “p-type semiconductor blocks” hereinafter) and a plurality of semiconductor blocks including an n-type thermoelectric conversion material (referred to as “n-type semiconductor blocks” hereinafter). The p-type semiconductor blocks and the n-type semiconductor blocks are alternately arranged in an in-plane direction of the heat transfer plates and are coupled to each other in series through metal terminals disposed between the semiconductor blocks. Lead electrodes are respectively connected to two ends of the semiconductor blocks coupled in series.

When there is a difference in temperature between the two heat transfer plates, a potential is generated between a p-type semiconductor block and an n-type semiconductor block due to the Seebeck effect, and electric power is output through the lead electrodes. When a power source is coupled to a pair of lead electrodes and electric current is supplied to the thermoelectric conversion module, heat is transferred from one heat transfer plate to the other by the Peltier effect.

The number of pairs of the p-type semiconductor blocks and the n-type semiconductor blocks, for example, several ten to several hundreds of the pairs may be used.

A semiconductor substrate, e.g., a thermoelectric conversion material substrate may be divided to a large number of semiconductor blocks with a dicing saw. The semiconductor blocks are aligned on heat transfer plates to form a thermoelectric conversion module. The metal terminals electrically coupling between the semiconductor blocks include a metal thin film or a conductive paste.

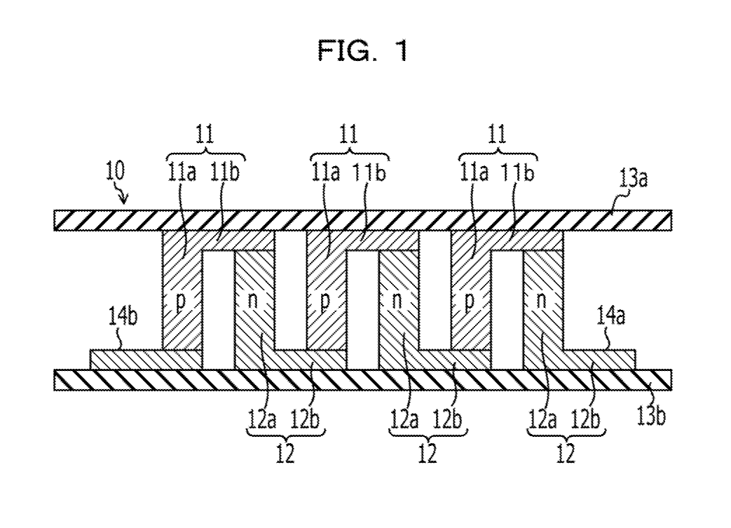

FIG. 1 illustrates an exemplary thermoelectric conversion module.

A thermoelectric conversion module 10 includes heat transfer plates 13a and 13b, and p-type semiconductor blocks 11 and n-type semiconductor blocks 12 interposed between the heat transfer plates 13a and 13b. The p-type semiconductor blocks 11 include a p-type thermoelectric conversion material such as Ca₃Co₄O₉, for example. The n-type semiconductor blocks 12 include an n-type thermoelectric conversion material such as Ca_{0.9}La_{0.1}MnO₃, for example.

The p-type semiconductor block 11 has a letter-L shape and includes a column portion 11a having a shape of a rectangular prism and a coupling portion 11b that projects in a horizontal direction from an end of the column portion 11a and has a shape of a thin plate. The n-type semiconductor blocks 12 also has a letter-L shape and includes a column portion 12a having a shape of a rectangular prism and a coupling portion 12b that projects in a horizontal direction from an end of the column portion 12a and has a shape of a thin plate.

In the thermoelectric conversion module 10, the coupling portions 11b of the p-type semiconductor blocks 11 are disposed on the heat transfer plate 13a, and the coupling portions 12b of the n-type semiconductor blocks 12 are disposed on the heat transfer plate 13b. The coupling portions 11b of the p-type semiconductor blocks 11 are respectively superimposed on ends (ends remote from the coupling portions 12b) of the column portions 12a of the n-type semiconductor blocks 12. The coupling portions 12b of the n-type semiconductor blocks 12 are respectively superimposed on ends (ends remote from the coupling portions 11b) of the column portions 11a of the p-type semiconductor blocks 11. The p-type semiconductor blocks 11 and the n-type semiconductor blocks 12 are arranged alternately and coupled to each other in series.

The heat transfer plates 13a and 13b each include, for example, a plate-shaped member including a material having good thermal conductivity, such as aluminum or copper. At least the surfaces of the heat transfer plates 13a and 13b, which make contact with the semiconductor blocks 11 and 12, may be subjected to an electric insulating treatment.

In the thermoelectric conversion module 10, the coupling portion 12b of the rightmost n-type semiconductor block 12 may correspond to a lead electrode 14a. An n-type semiconductor thin plate coupling to the column portion 11a of the leftmost p-type semiconductor block 11 may correspond to a lead electrode 14b.

When a temperature difference is created between the heat transfer plates 13a and 13b, current flows between the p-type semiconductor blocks 11 and the n-type semiconductor blocks 12, and power may be output from the lead electrodes 14a and 14b. The thermoelectric conversion module 10 may be used as a peltier element. For example, when the voltage is applied to the lead electrodes 14a and 14b, the heat transfers from the heat transfer plate 13a to the heat transfer plate 13b or vise versa.

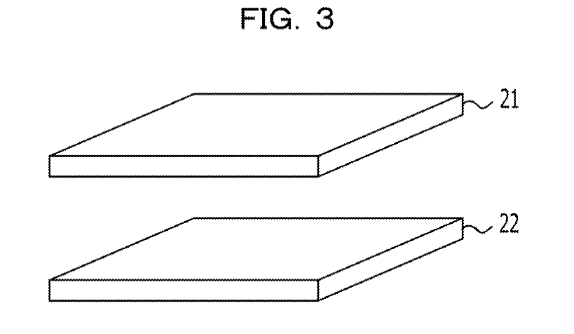

FIGS. 3 to 8 illustrate an exemplary method of a thermoelectric conversion module.

In operation S11, as illustrated in FIG. 3, a p-type semiconductor substrate (p-type thermoelectric conversion material substrate) 21 for the p-type semiconductor blocks 11 and an n-type semiconductor substrate (n-type thermoelectric conversion material substrate) 22 for the n-type semiconductor blocks 12 are formed.

The thickness of the p-type semiconductor substrate 21 and the n-type semiconductor substrate 22 may be 900 μm. The p-type semiconductor substrate 21 may include Ca₃Co₄O₉ and the n-type semiconductor substrate 22 may include Ca_{0.9}La_{0.1}MnO₃. The p-type semiconductor substrate 21 and the n-type semiconductor substrate 22 may include other thermoelectric conversion materials. The p-type thermoelectric conversion material may include NaₓCoO₂ or Ca₃₋ₓBiₓCo₄O₉, for example. The n-type thermoelectric conversion material may include La_{0.9}Bi_{0.1}NiO₃, CaMn_{0.98}Mo_{0.02}O₃, or Nb-doped SrTiO₃, for example.

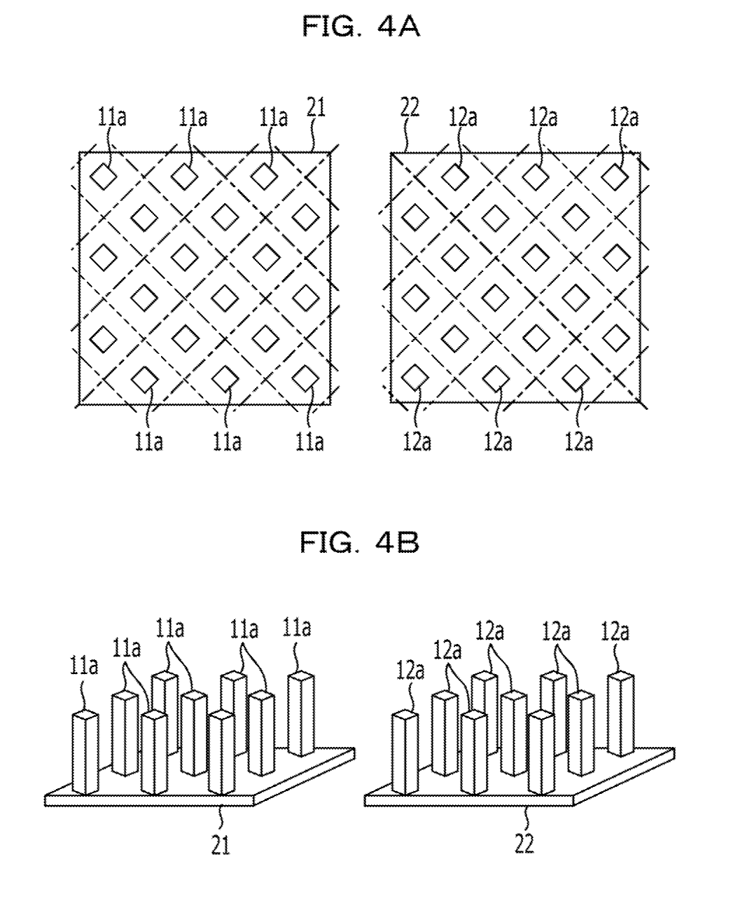

In operation S12, as illustrated in a plan view of FIG. 4A and a perspective view of FIG. 4B, incisions (grooves) forming a grid pattern and having a depth of about 800 μm are formed in the p-type semiconductor substrate 21 by a dicing saw. The dashed-dotted lines in FIG. 4A may correspond to the paths in which the dicing saw travels. The portions surrounded by the incisions may correspond to the column portions 11a of the p-type semiconductor blocks 11. The p-type semiconductor substrate 21 with a thickness of about 100 μm may remain in the incisions (groove bottoms). The semiconductor substrate that remains in the incisions may be referred to as “thin-plate portion”. Part of the thin-plate portion may correspond to the coupling portions 11b of the p-type semiconductor blocks 11.

Referring to FIG. 4A, the size of each column portion 11a may be 100 μm×100 μm. The height of the column portion 11 may be 800 μm. The intervals between the column portions 11a in a direction parallel to the dashed-dotted lines in FIG. 4 may be 200 μm, for example. The intervals between the column portions 11a may be adjusted based on the thickness of the blade of the dicing saw or the number of times of incising.

Incisions (grooves) forming a grid pattern and having a depth of about 800 μm are formed in the n-type semiconductor substrate 22 so as to form column portions 12a of the n-type semiconductor blocks 12. The size of the column portions 12a may be 100 μm×100 μm, the height may be 800 μm, and the intervals between the column portions 12a may be 200 μm. The column portions 11a and 12a are formed by forming the incisions in the semiconductor substrates 21 and 22 with a dicing saw. Alternatively, for example, grooves may be formed in the semiconductor substrates 21 and 22 by blasting so as to form the column portions 11a and 12a.

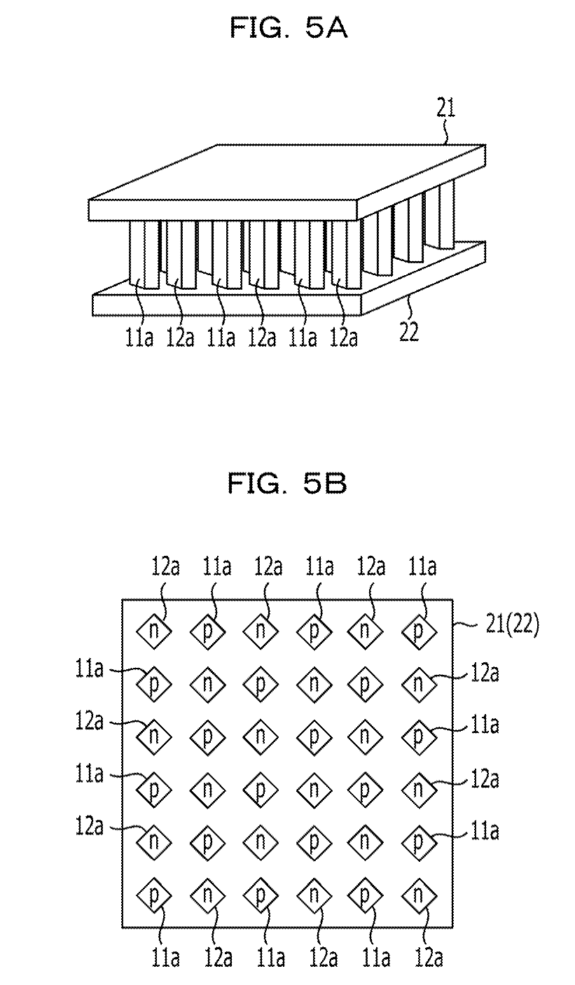

In operation S13, as illustrated in FIG. 5A, the p-type semiconductor substrate 21 and the n-type semiconductor substrate 22 are superimposed on each other so that the incised surface of the p-type semiconductor substrate 21 faces the incised surface of the n-type semiconductor substrate 22. As illustrated in FIG. 5B, the column portions 11a of the p-type semiconductor blocks 11 and the column portions 12a of the n-type semiconductor blocks 12 are inserted so that the column portions 11a and the column portions 12a are alternately arranged.

As illustrated in FIG. 5B, the p-type semiconductor block 11 and the n-type semiconductor blocks 12, which is adjacent to the p-type semiconductor block 11, are provided so that the corner of the column portion 11a faces the corner of the column portion 12a.

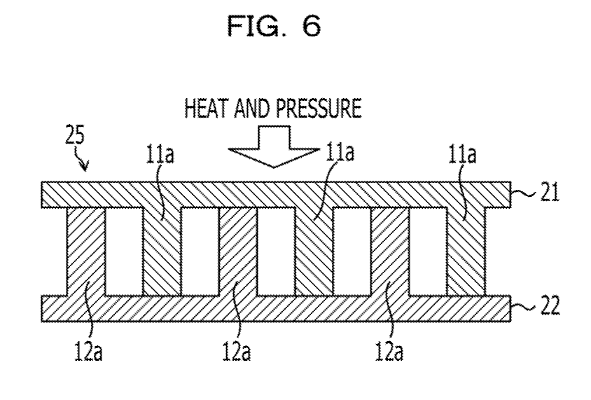

Referring now to FIG. 6, the p-type semiconductor substrate 21 and the n-type semiconductor substrate 22 are bonded (thermally bonded) to each other by applying temperature and pressure through a hot pressing. In the hot-pressing process, the tips of the column portions 11a are bonded to the thin-plate portions of the n-type semiconductor substrate 22, and the tips of the column portions 12a are bonded to the thin-plate portions of the p-type semiconductor substrate 21. The conditions of the hot-pressing may be, for example, a pressure of 10 MPa to 50 MPa and a temperature of 900° C. to 1000° C. The conditions of the hot-pressing may be any other conditions as long as the column portions 11a and 12a are satisfactorily electrically bonded to the thin-plate portions of the semiconductor substrates 21 and 22. The two substrates, i.e., the semiconductor substrates 21 and 22, may be referred to as a “bonded substrate 25”.

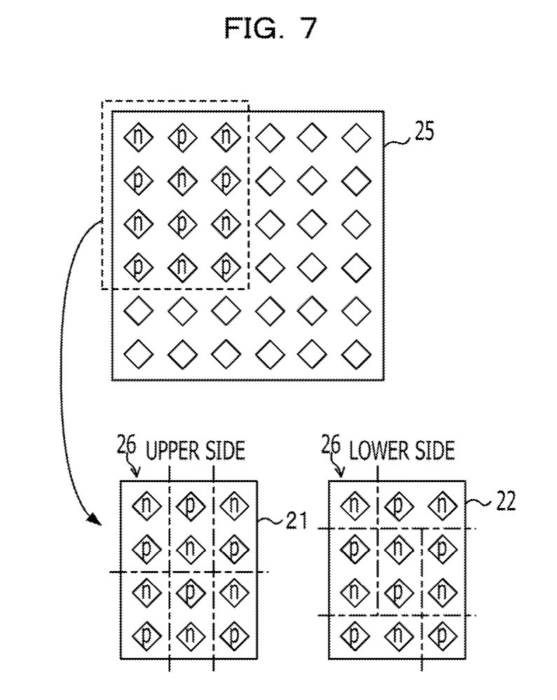

In operation S14, as illustrated in FIG. 7, the bonded substrate 25 is cut and divided into a certain size. Then the process proceeds to operation S15. A dicing saw forms incisions in the thin-plate portions of the p-type semiconductor substrate 21 and the n-type semiconductor substrate 22 so that the p-type semiconductor blocks 11 and the n-type semiconductor blocks 12 are alternately arranged and coupled to each other in series. The thin-plate portions of the p-type semiconductor substrate 21 and the n-type semiconductor substrate 22 may be the coupling portions 11b and 12b.

In FIG. 7, the rectangular portion surrounded by a broken line is cut out by the dicing saw from the bonded substrate 25. Then incisions, e.g., the portions indicated by the dashed-dotted line in FIG. 7, are formed in the p-type semiconductor substrate 21 and the n-type semiconductor substrate 22 so as to form a semiconductor block assembly 26 that includes the p-type semiconductor blocks 11 and the n-type semiconductor blocks 12 alternately arranged and coupled with each other in series. The incisions may be made by using other machines, such as an ultrasonic process machine or a laser dicing machine.

As illustrated in FIGS. 4A and 7, the direction in which the incisions, e.g., grooves, extend during formation of the column portions 11a and 12a, e.g., the directions indicated by the dashed-dotted lines in FIG. 4A, may intersect at an angle of 45° with the directions in which incisions extend in the bonded substrate 25, i.e., the directions indicated by the dashed-dotted lines in FIG. 7.

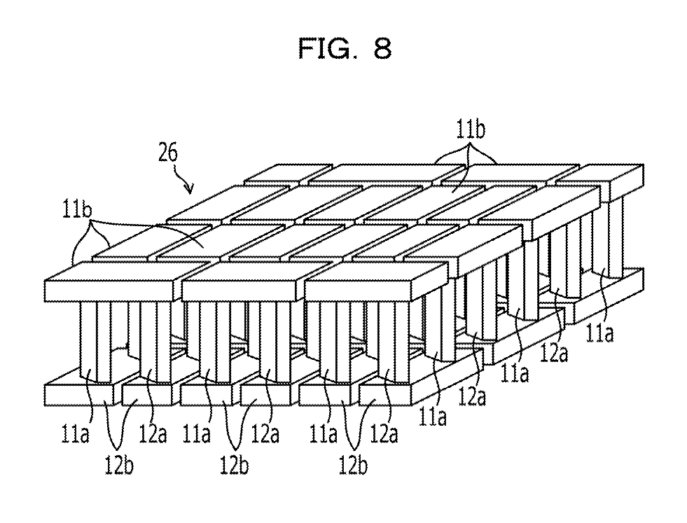

FIG. 8 illustrates exemplary semiconductor blocks. In FIG. 8, incisions are formed so that the semiconductor blocks 11 and 12 are arranged alternately and coupled to each other in series. FIG. 8 may be a perspective view of the semiconductor block assembly 26. In operation S16, the heat transfer plates 13a and 13b may be attached to the semiconductor block assembly 26 with, for example, a heat-conducting adhesive to form the thermoelectric conversion module 10 illustrated in FIG. 1. Instead of attaching the heat transfer plates 13a and 13b, the semiconductor block assembly 26 may be attached to an electronic device corresponding to the heat source to form a thermoelectric conversion module.

In order to investigate the thermo-electric characteristics of the thermoelectric conversion module, the size of the thermoelectric conversion module may be set to about 2 mm×about 2 mm in size and about 1 mm in thickness. The number of the p-type semiconductor blocks 11 and the number of the n-type semiconductor blocks 12 may each be 100 (100 pairs). The temperature of one of the heat transfer plates of the thermoelectric conversion module may be set to room temperature and the temperature of the other heat transfer plate may be set to be 10° C. lower than the room temperature. Under such conditions, a voltage of about 0.1 V was generated between the output terminals.

In the thermoelectric conversion module 10, as illustrated in FIG. 1, the p-type semiconductor blocks 11 are directly bonded to the n-type semiconductor blocks 12. Thus, the metal terminals that electrically couple between the p-type semiconductor blocks 11 the n-type semiconductor blocks 12 may not be provided. The process of dividing the semiconductor blocks into individual pieces and the process of arranging the individual semiconductor blocks may be omitted. Accordingly, the number of processes for manufacturing the thermoelectric conversion module may be reduced, and the production cost for the thermoelectric conversion module may be reduced.

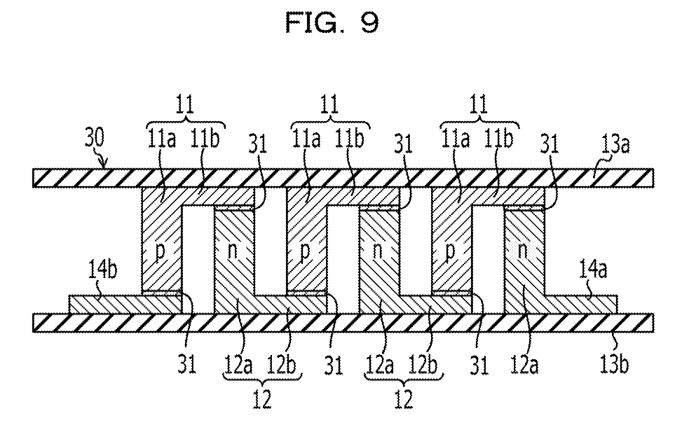

FIG. 9 illustrates an exemplary thermoelectric conversion module. The thermoelectric conversion module illustrated in FIG. 9 includes metal layers 31 at the junctions between the p-type semiconductor blocks 11 and the n-type semiconductor blocks 12. Other structures may be substantially the same or similar to the structure of the thermoelectric conversion module illustrated in FIG. 1. In FIG. 9, elements that are substantially equivalent to those illustrated in FIG. 1 are referenced by the same symbols and the descriptions may be omitted or reduced.

The thermoelectric conversion module 10 illustrated in FIG. 1 includes the p-type semiconductor blocks 11 and the n-type semiconductor blocks 12 directly bonded to each other.

In contrast, a thermoelectric conversion module 30 illustrated in FIG. 9 includes the metal layers 31 including, for example, Ag (silver) are interposed at the junctions between the p-type semiconductor blocks 11 and the n-type semiconductor blocks 12. Thus, atoms may not move between the p-type semiconductor blocks 11 and the n-type semiconductor blocks 12. As a result, the electrical characteristics of the junctions between the p-type semiconductor blocks 11 and the n-type semiconductor blocks 12 may be stabilized and the reliability of the thermoelectric conversion module may be improved.

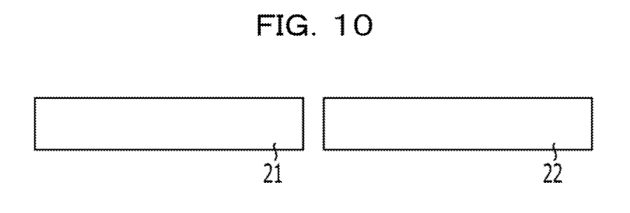

FIGS. 10 to 13 illustrate an exemplar method for making a thermoelectric conversion module. In FIGS. 10 to 13, the elements that are substantially equivalent to those illustrated in FIGS. 3 to 8 are referenced by the same symbols.

As illustrated in FIG. 10, the p-type semiconductor substrate 21 including a p-type thermoelectric conversion material such as Ca₂Co₄O₉ and the n-type semiconductor substrate 22 including an n-type thermoelectric conversion material such as Ca_{0.9}La_{0.1}MnO₃ are formed. The thickness of the p-type semiconductor substrate 21 and the n-type semiconductor substrate 22 may be 900 μm.

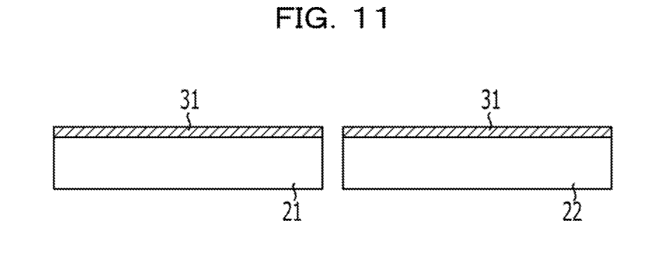

Referring to FIG. 11, the metal layers 31 having a thickness of, for example, 2 μm are respectively formed on the p-type semiconductor substrate 21 and the n-type semiconductor substrate 22. After silver is deposited to a thickness of 0.5 μm by vacuum vapor deposition, a silver paste is applied to a thickness of 1.5μ to form silver layers as the metal layers 31. For example, the p-type semiconductor substrate 21 and the n-type semiconductor substrate 22 may be heat-treated at 800° C. for about 10 minutes. The metal layers 31 may include gold (Au), solder, etc.

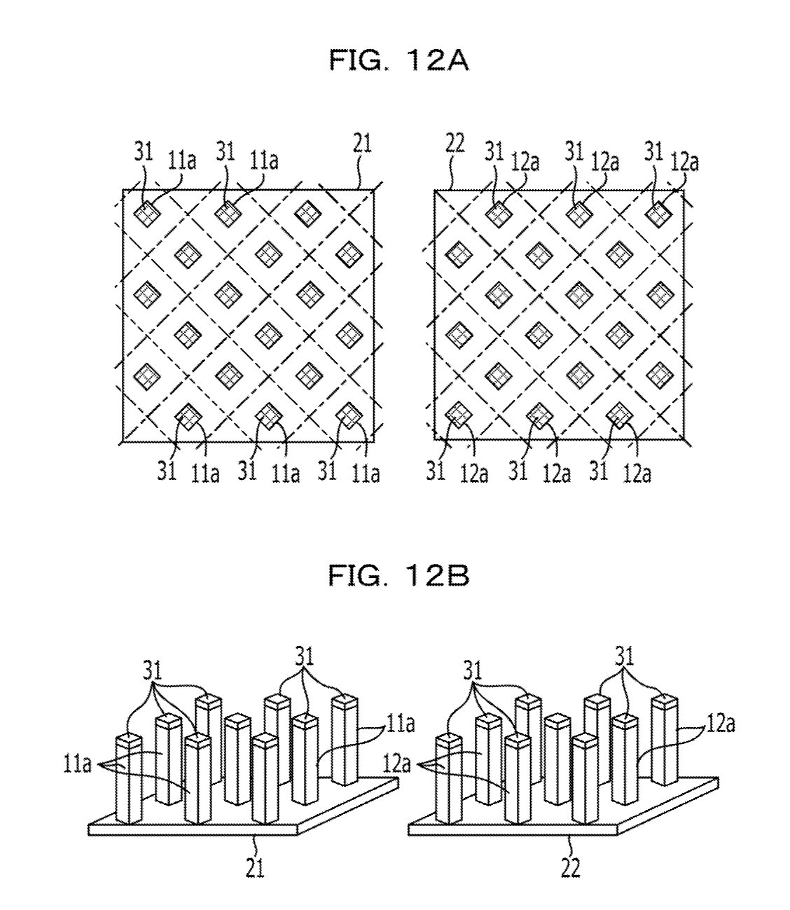

As illustrated in FIGS. 12A and 12B, a dicing saw forms incisions having a depth of about 800 μm in the p-type semiconductor substrate 21 and the n-type semiconductor substrate 22. For example, the incisions may be grooves that are arranged in a grid pattern. The rectangular prism portions surrounded by the incisions (grooves) in the p-type semiconductor substrate 21 may correspond to the column portions 11a of the p-type semiconductor blocks 11. The rectangular prism portions surrounded by the incisions (grooves) in the n-type semiconductor substrate 22 may correspond to the column portions 12a of the n-type semiconductor blocks 12. The tops of the column portions 11a and 12a are covered with the metal layers 31.

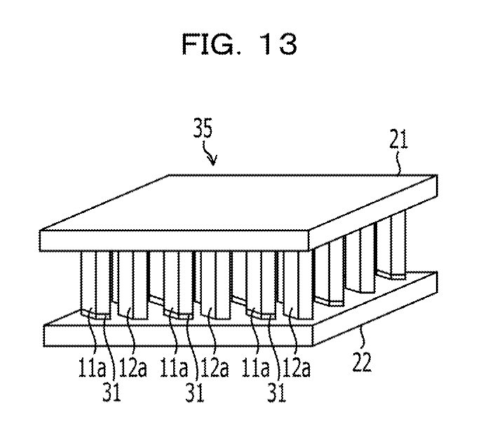

As illustrated in FIG. 13, the p-type semiconductor substrate 21 and the n-type semiconductor substrate 22 are superimposed on each other so that the incised surface of the p-type semiconductor substrate 21 faces the incised surface of the n-type semiconductor substrate 22. The column portions 11a are inserted into the gaps between the column portions 12a so that the column portions 11a of the p-type semiconductor blocks 11 and the column portions 12a of the n-type semiconductor blocks 12 are arranged alternately in the vertical direction and the horizontal direction.

For example, the p-type semiconductor substrate 21 and the n-type semiconductor substrate 22 are heat-treated at 700° C. to 900° C. to bond the p-type semiconductor substrate 21 and the n-type semiconductor substrate 22 through the metal layers 31 to form a bonded substrate 35. The strong pressure may not be applied to the semiconductor substrates 21 and 22. The pressure may be sufficient to increase the bonding strength. The p-type semiconductor substrate 21 may be bonded to the n-type semiconductor substrate 22 through hot pressing by heating at 900° C. to 1000° C. while applying a pressure of about 10 MPa to 50 MPa.

The bonded substrate 35 is cut into pieces of a desired size. A dicing saw or the like forms incisions in the thin-plate portions of the p-type semiconductor substrate 21 and the n-type semiconductor substrate 22 so that the p-type semiconductor blocks 11 and the n-type semiconductor blocks 12 are alternately arranged and coupled to each other in series, thereby forming a semiconductor block assembly. The heat transfer plates 13a and 13b are attached to the semiconductor block assembly with, for example, a heat-conducting adhesive, to form the thermoelectric conversion module 30 illustrated in FIG. 9.

The metal layers 31 may reduce diffusion of atoms between the p-type semiconductor blocks 11 and the n-type semiconductor blocks 12 and improve the reliability of the joints between the semiconductor blocks 11 and 12.

The depth of the incisions may vary during formation of the incisions (grooves) with a dicing saw. However, since the p-type semiconductor substrate 21 is bonded to the n-type semiconductor substrate 22 through the metal layers 31, such a variation in depth may be compensated by the metal layers 31 working as a cushioning material. As a result, the connection between the p-type semiconductor substrate 21 and the n-type semiconductor substrate 22 may be ensured, and the reliability of the joints between the semiconductor blocks 11 and 12 may be improved.

Prior to bonding the p-type semiconductor substrate 21 to the n-type semiconductor substrate 22, a silver paste may be applied on the metal layers 31. This may help ensure the connection between the p-type semiconductor substrate 21 and the n-type semiconductor substrate 22 even when the variation in depth of incisions is great. Alternatively, the metal layers 31 may not be formed and a conductive bonding layer including a conductive material such as a silver paste may be formed on the column portions 11a and 12a prior to bonding of the p-type semiconductor substrate 21 to the n-type semiconductor substrate 22.

The size of the thermoelectric conversion module may be about 2 mm×about 2 mm and the thickness may be about 1 mm. The number of the p-type semiconductor blocks 11 and the number of the n-type semiconductor blocks 12 may each be 100 (100 pairs). The temperature of one of the heat transfer plates of the thermoelectric conversion module may be set to room temperature and the temperature of the other heat transfer plate may be set to be 10° C. lower than the room temperature. A voltage of about 0.1 V may be generated between the output terminals.

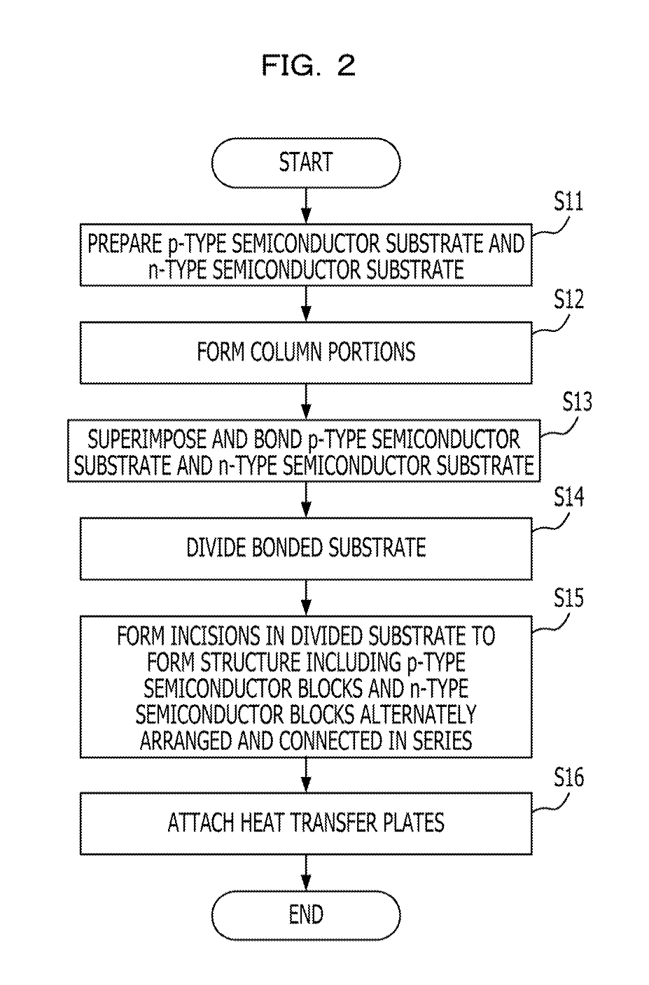

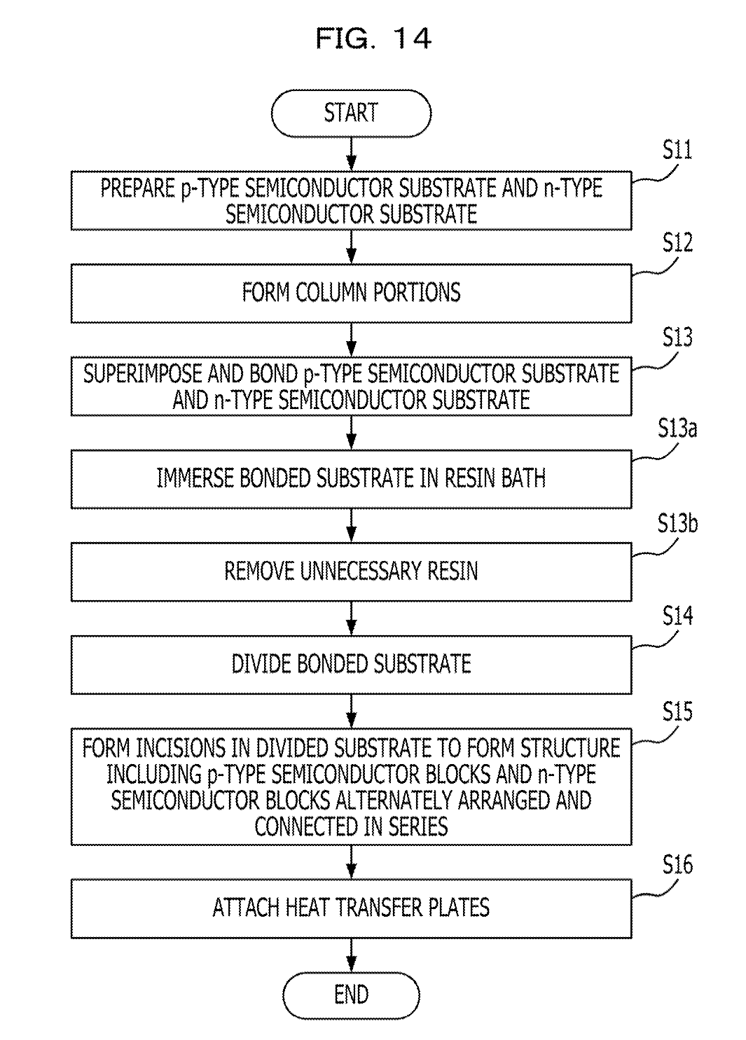

FIG. 14 illustrates an exemplary method for making a thermoelectric conversion module. The method illustrated in FIG. 14 includes the method illustrated in FIG. 2 and the operations S13a and S13b. Other operations may be substantially the same or similar to those illustrated in FIG. 2.

The bonded substrate 25 is prepared by bonding the p-type semiconductor substrate 21 to the n-type semiconductor substrate 22 as illustrated in FIGS. 5 and 6. In operation S13a, for example, the bonded substrate 25 is immersed in a resin bath in a reduced-pressure chamber to fill the gaps between the column portions 11a and 12a. The resin may include a resin having high heat insulating property and electrical insulating property. For example, urethane or other types of synthetic rubber may be included.

The bonded substrate 25 is then pulled out from the resin bath and the resin is cured. In operation S13b, the resin adhering onto the outer side of the bonded substrate 25 is removed by polishing or the like. The subsequent processes may be substantially the same or similar to those of the method illustrated in FIG. 2. Metal layers may be provided between the p-type semiconductor blocks 11 and the n-type semiconductor blocks 12.

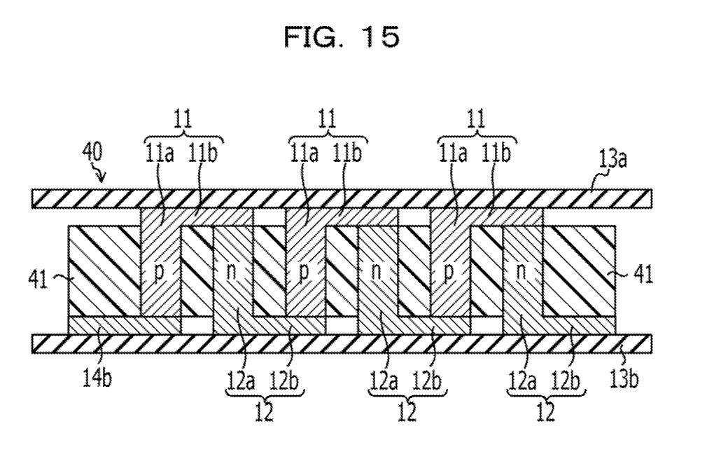

FIG. 15 illustrates an exemplary thermoelectric conversion module. A thermoelectric conversion module 40 illustrated in FIG. 15 may be made by the method illustrated in FIG. 14. The thermoelectric conversion module illustrated in FIG. 15 includes an electrically insulating resin (filler) 41 filling the gaps between the column portions 11a of the p-type semiconductor blocks 11 and the column portions 12a of the n-type semiconductor blocks 12. Therefore, the mechanical strength of the thermoelectric conversion module 40 improves and the breaking and damage occurring during operation may be reduced. Thus, breaking and damage in the manufacturing process may be avoided and the yield of production of the thermoelectric conversion module may improve. All examples and conditional language recited herein are intended for pedagogical objects to aid the reader in understanding the invention and the concepts contributed by the inventor to furthering the art, and are to be construed as being without limitation to such specifically recited examples and conditions. Although the embodiment(s) of the present inventions have been described in detail, it should be understood that the various changes, substitutions, and alterations could be made hereto without departing from the spirit and scope of the invention.

1. A thermoelectric conversion module comprising:
p-type semiconductor blocks, each including a p-type thermoelectric conversion material, a first column portion and a first coupling portion that projects in a horizontal direction from an end of the first column portion; and
n-type semiconductor blocks, each including an n-type thermoelectric conversion material, a second column portion and a second coupling portion that projects in a horizontal direction from an end of the second column portion,
wherein the first coupling portions of the p-type semiconductor blocks are respectively coupled to the other ends of the second column portions of the n-type semiconductor blocks, and the second coupling portions of the n-type semiconductor blocks are respectively coupled to the other ends of the first column portions of the p-type semiconductor blocks, and
the p-type semiconductor blocks and the n-type semiconductor blocks are alternately arranged and coupled to each other in series.

2. The thermoelectric conversion module according to claim 1, further comprising:
a metal layer interposed between the first coupling portion and the second column portion; and
a metal layer interposed between the second coupling portion and the first column portion.

3. The thermoelectric conversion module according to claim 1, further comprising:
a pair of heat transfer plates arranged so as to sandwich the p-type semiconductor blocks and the n-type semiconductor blocks,
wherein the first coupling portions of the p-type semiconductor blocks are disposed on one of the heat transfer plates, and
the second coupling portions of the n-type semiconductor block are disposed on the other one of the heat transfer plates.

4. The thermoelectric conversion module according to claim 1, wherein
at least one of the first column portions and at least one of the second column portions have a shape of a rectangular prism, and
one of the p-type semiconductor blocks and one of the n-type semiconductor blocks which are adjacent each other are arranged such that a corner of the first column portion of the one of the p-type semiconductor blocks faces a corner of the second column portion of the one of the n-type semiconductor blocks.

5. The thermoelectric conversion module according to claim 1, wherein the p-type semiconductor blocks and the n-type semiconductor blocks are arranged in a grid pattern.

6. The thermoelectric conversion module according to claim 1, wherein at least one of the first coupling portions and the second coupling portions is plate-shaped.

7. The thermoelectric conversion module according to claim 1, wherein a width of the first coupling portion of one of the p-type semiconductor blocks is greater than that of the first column portion of the one p-type semiconductor block, or a width of the second coupling portion of one of the n-type semiconductor blocks is greater than that of the second column portion of the one n-type semiconductor block.

8. The thermoelectric conversion module according to claim 5, wherein at least one of the p-type semiconductor blocks and the n-type semiconductor blocks arranged in a grid pattern is located in a peripheral portion and has a conductivity type different from that of an adjacent semiconductor block.

9. The thermoelectric conversion module according to claim 1, further comprising:
an electrically insulating filler that fills spaces between the first column portion and the second column portion.

10. The thermoelectric conversion module according to claim 1, wherein the p-type thermoelectric conversion material includes a compound containing at least one of Ca₃Co₄O₉, NaₓCoO₂, and Ca₃₋ₓBiₓCo₄O₉, and
the n-type thermoelectric conversion material includes a compound containing at least one of Ca_{0.9}La_{0.1}MnO₃, La_{0.9}Bi_{0.1}NiO₃, CaMn_{0.02}Mo_{0.02}O₃, and Nb-doped SrTiO₃.

11. A method for manufacturing a thermoelectric conversion module, comprising:
forming first grooves arranged in a grid pattern in a first substrate that includes a p-type thermoelectric conversion material to form first column portions surrounded by the first grooves;
forming second grooves arranged in a grid pattern in a second substrate that includes an n-type thermoelectric conversion material to form second column portions surrounded by the second grooves;
superimposing the first substrate and the second substrate to each other with the grooved surfaces of the first and second substrates facing inward and the first column portions and the second column portions being alternately arranged;
bonding the first column portions to the second grooves in the second substrate and the second column portions to the first grooves in the first substrate to form a bonded substrate; and
forming incisions in the first grooves of the first substrate and the second grooves of the second substrate.

12. The method according to claim 11, further comprising:
alternately arranging and coupling in series p-type semiconductor blocks including the p-type thermoelectric conversion material and n-type semiconductor blocks including the n-type thermoelectric conversion material.

13. The method according to claim 11, further comprising:
forming a metal layer on a surface of the first substrate in which the first grooves are formed; and
forming a metal layer on a surface of the second substrate in which the second grooves are formed.

14. The method according to claim 11, further comprising:
forming a conductive bonding layer on the first column portions and the second column portions.

15. The method according to claim 11, wherein the first and second grooves are respectively formed in the first substrate and the second substrate with a dicing saw.

16. The method according to claim 11, wherein a direction in which the first and second grooves extend intersects substantially at an angle of 45° with a direction in which the incisions formed in the first substrate and the second substrate extend.

17. The method according to claim 11, further comprising:
filling inside of the bonded substrate with an electrically insulating filler.

18. The method according to claim 11, wherein the p-type thermoelectric conversion material includes a compound including at least one of Ca₃Co₄O₉, NaₓCoO₂, and Ca₃₋ₓBiₓCo₄O₉, and
the n-type thermoelectric conversion material includes a compound including at least one of Ca_{0.9}La_{0.1}MnO₃, La_{0.9}Bi_{0.1}NiO₃, CaMn_{0.98}Mo_{0.02}O₃, and Nb-doped SrTiO₃.
